(19) United States
(12) Patent Application Publication
(10) Pub. No.: US 2025/0231116 A1
(43) Pub. Date: Jul. 17, 2025

(54) METHOD FOR OBSERVING SURFACE

(71) Applicants: Tokyo Electron Limited, Tokyo (JP); Kyoto University, Kyoto (JP)

(72) Inventors: Shin OOWADA, Tokyo (JP); Ryuichi ASAKO, Yamanashi (JP); Satoru SHIMURA, Kumamoto (JP); Kazuo TANAKA, Kyoto (JP); Shunichiro ITO, Kyoto (JP); Yoshiki CHUJO, Kyoto (JP); Kazuhiro YUHARA, Kyoto (JP)

(73) Assignees: Tokyo Electron Limited, Tokyo (JP); Kyoto University, Kyoto (JP)

(21) Appl. No.: 19/170,104

(22) Filed: Apr. 4, 2025

Related U.S. Application Data
(63) Continuation of application No. PCT/JP2023/035017, filed on Sep. 26, 2023.

(30) Foreign Application Priority Data
Oct. 5, 2022 (JP) 2022-160720

(51) Int. Cl. G01N 21/88; G01N 21/64; G01N 21/95

(52) U.S. Cl. CPC G01N 21/8806; G01N 21/643; G01N 21/6456; G01N 21/8851; G01N 21/9501; G01N 2021/6439; G01N 2021/8874

(57) ABSTRACT

A method for observing a surface includes a) and b). At the a), a material including at least one or more solid luminescent dye molecules is accumulated in a region having an abnormal shape in a substrate or in a structure on the substrate. At the b), the region having the abnormal shape in the substrate or in the structure on the substrate is irradiated with illumination light to acquire the fluorescent image of the solid luminescent dye molecules.

### CROSS-REFERENCE TO RELATED APPLICATIONS

This application is a continuation application of International Application No. PCT/JP2023/035017, filed on Sep. 26, 2023, which claims the benefit of priority of the prior Japanese Patent Application No. 2022-160720, filed on Oct. 5, 2022, the entire contents of each are incorporated herein by reference.

### FIELD

Various aspects and exemplary embodiments disclosed herein relate to a method for observing a surface.

### BACKGROUND

“Design of Stimuli-responsive Solid-state Luminescent Materials Based on Flexible Boron Element-blocks”, Issei Tanaka and other two researchers, Journal of the Imaging Society of Japan, vol. 58, No. 1, pp. 81-92 (2019) has disclosed the following: “General organic luminescent dyes lose most of their luminescence properties in solids. It is thought that in an aggregated state, intermolecular interaction strongly occurs in a ground state and an excited state, causing quenching of luminescence. This phenomenon is called concentration quenching.”

In addition, “Design of stimulation-responsive luminescent material using flexible boron molecule block as base”, Issei Tanaka and other two researchers, Journal of the Imaging Society of Japan, vol. 58, No. 1, pp. 81-92 (2019) also has disclosed the following: “AIE is a phenomenon that Tang et al. reported to occur in pentaphenylsilole in 2001. This molecules indicate the opposite behavior to that of conventional organic dyes in which no luminescence phenomenon is observed in solution, but luminescence intensity increases in aggregation or in a solid state. As the cause of this phenomenon, it is explained that the decay of the excited state is accelerated by molecular motion in solution, whereas in the aggregated state, the deactivation process associated with the molecular motion is inhibited, resulting in achieving the luminescence.”

In addition, Japanese Laid-open Patent Publication No. H4-343003 has disclosed the following: “A sample surface is obliquely irradiated with excitation light partially or around the entire circumference to reduce background noise, the amount of fluorescent light from resist residues is increased, and the sample surface is vertically irradiated with the excitation light to ensure the detection of the resist residues adhering to the bottom of a trench.”

The present disclosure provides a method for observing a surface that can accurately detect an abnormal shape in a substrate or in a structure on the substrate having a size of several tens of nanometers.

### SUMMARY

According to an aspect of an embodiment, a method for observing a surface includes a) and b).

At the a), a material including at least one or more solid luminescent dye molecules is accumulated in a region having an abnormal shape in a substrate or in a structure on the substrate. At the b), the fluorescent image of the solid luminescent dye molecules is acquired by irradiating the region with illumination.

### BRIEF DESCRIPTION OF DRAWINGS

FIG. 1 is a flowchart illustrating one example of a method for observing a surface in a first exemplary embodiment;

FIG. 2 is a view illustrating one example of the procedure of the method for observing a surface in the first exemplary embodiment;

FIG. 3 is a view illustrating one example of the procedure of the method for observing a surface in the first exemplary embodiment;

FIG. 4 is a view illustrating one example of the procedure of the method for observing a surface in the first exemplary embodiment;

FIG. 5 is a view illustrating one example of the procedure of the method for observing a surface in the first exemplary embodiment;

FIG. 6 is a photograph illustrating one example of an image of the surface of a substrate;

FIG. 7 is a cross-sectional view illustrating one example of a state of the substrate in a frame in FIG. 6;

FIG. 8 is a graph illustrating one example of the distribution of luminescence intensity for each scratch width in a second exemplary embodiment;

FIG. 9A is a view illustrating one example of a process of embedding the crystal grains of a fluorescent material in a scratch;

FIG. 9B is a view illustrating one example of the process of embedding the crystal grains of the fluorescent material in the scratch;

FIG. 10 is a flowchart illustrating one example of the method for observing a surface in a third exemplary embodiment;

FIG. 11 is a view illustrating one example of the procedure of the method for observing a surface in the third exemplary embodiment;

FIG. 12 is a view illustrating one example of the procedure of the method for observing a surface in the third exemplary embodiment;

FIG. 13 is a graph illustrating one example of the distribution of the luminescence intensity for each resist thickness;

FIG. 14 is a graph illustrating one example of the relationship between a resist thickness and a light exposure amount;

FIG. 15 is a view illustrating another example of the state of a resist; and

FIG. 16 is a view illustrating one example of a computer hardware configuration.

### DESCRIPTION OF EMBODIMENTS

Hereinafter, exemplary embodiments of a method for observing a surface will be explained in detail with reference to the accompanying drawings. The disclosed method for observing a surface is not limited to the exemplary embodiments explained below.

Incidentally, in the case where semiconductor devices with process rules at a several tens of nanometer level are produced, scratches, particles, and other defects having a size of several tens of nanometers in a substrate affect the quality of the semiconductor devices. Therefore, before starting the process, it is necessary to inspect the presence or the absence of the scratches, particles, and other defects having a size of several tens of nanometers on substrates. As a method for inspecting scratches and other defects on substrates, fluorescent penetrant inspection methods have been known. The luminescent molecules used in conventional fluorescent penetrant inspection methods emit light in dilute solution.

In the case where the scratches are small, the number of luminescent molecules having entered the scratches is small, resulting in lower luminescence intensity. Therefore, a further increase in the luminescence intensity is desired in order to improve the detection accuracy of small scratches.

Although the luminescent molecules used in the conventional fluorescent penetrant inspection methods emit light in dilute solution, in an aggregated state with a high concentration of the luminescent molecules, the luminescent molecules do not emit light due to a phenomenon called concentration quenching. Therefore, when the luminescent molecules used in the conventional fluorescent penetrant inspection methods are used, the detection has been limited to scratches having about several micrometers.

Therefore, the present disclosure provides a technology that can accurately detect abnormal shapes in a substrate or in a structure on the substrate having a size of several tens of nanometers.

### First Exemplary Embodiment

### Method for Observing Surface

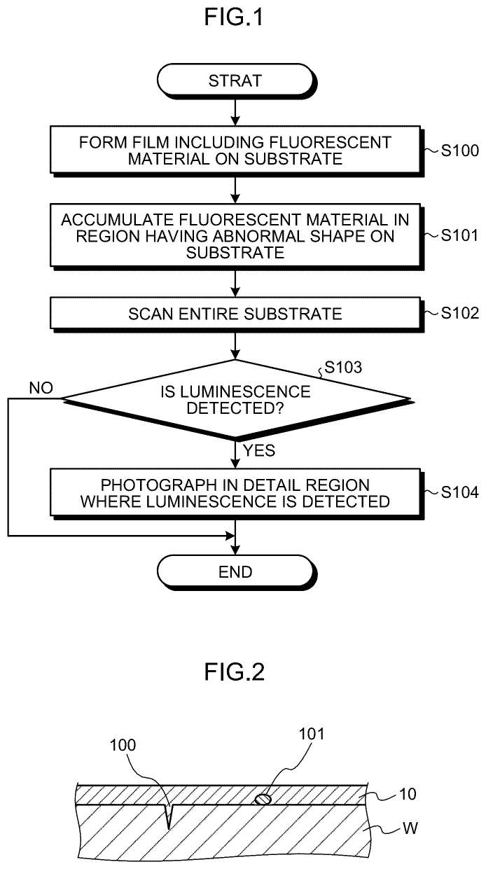

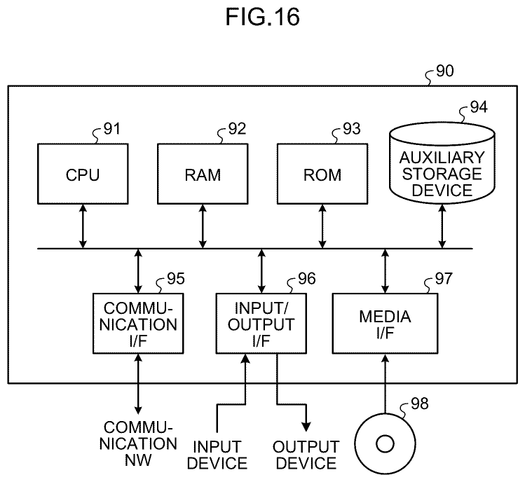

FIG. 1 is a flowchart illustrating one example of a method for observing a surface in the first exemplary embodiment. Each process in the flowchart exemplified in FIG. 1 is achieved by controlling each device using, for example, a computer 90 exemplified in FIG. 16.

In the method for observing a surface in the present exemplary embodiment, a film including a fluorescent material is firstly formed on a substrate W (S100). At Step S100, for example, a film 10 including the fluorescent material is formed on the substrate W as illustrated in FIG. 2. In the present exemplary embodiment, the film 10 is formed on the substrate W by, for example, vapor deposition. The film 10 may be formed on the substrate W by coating such as spin coating.

In the substrate W, a recess 100 and a protrusion 101 may exist, for example, as illustrated in FIG. 2. Examples of the recess 100 include a scratch, a crack, and a hole on the surface of the substrate W. Examples of the protrusion 101 include a particle adhering to the surface of the substrate W. The recess 100 and the protrusion 101 are examples of abnormal shapes of the substrate W. At Step S100, the recess 100 and the protrusion 101 are covered with the film 10 including the fluorescent material formed on the substrate W, for example, as illustrated in FIG. 2.

In the present exemplary embodiment, examples of the fluorescent material included in the film 10 include substances illustrated in following Chemical Formulas (1) to (9). The substances illustrated in following Chemical Formulas (1) to (9) are examples of solid luminescent dye molecules. Some of these substances are also luminescent dyes exhibiting luminescent mechanochromism.

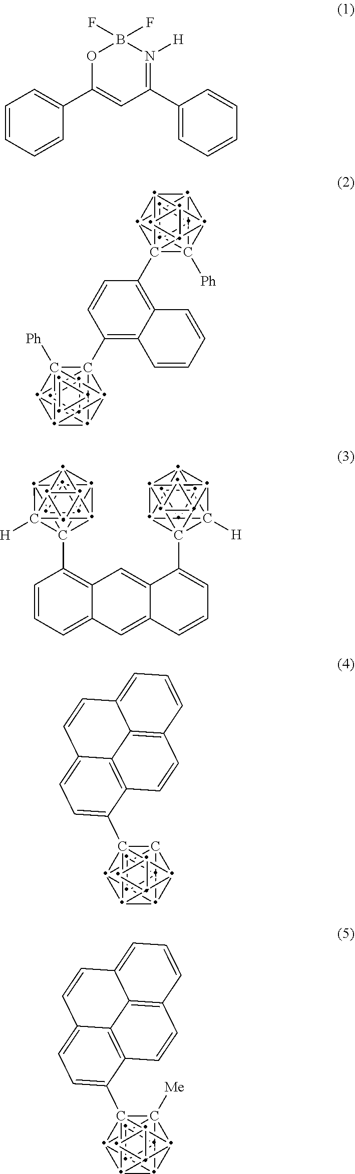

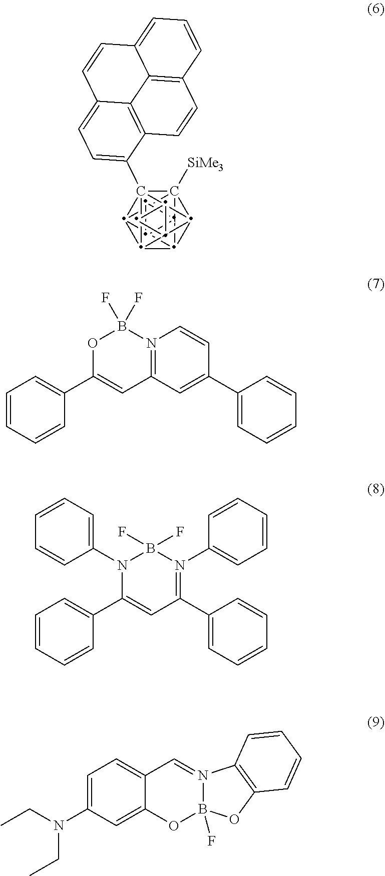

The mechanochromism is a phenomenon in which colors are changed by applying physical forces such as rubbing or crushing crystals. The phenomenon in which the luminescence colors are changed is called luminescent mechanochromism.

In above Chemical Formulas (2) to (6), the black circle represents a BH group having boron and hydrogen. At Step S100, the film 10 including at least one or more fluorescent materials having the structures illustrated in above Chemical Formulas (1) to (9) is formed on the substrate W.

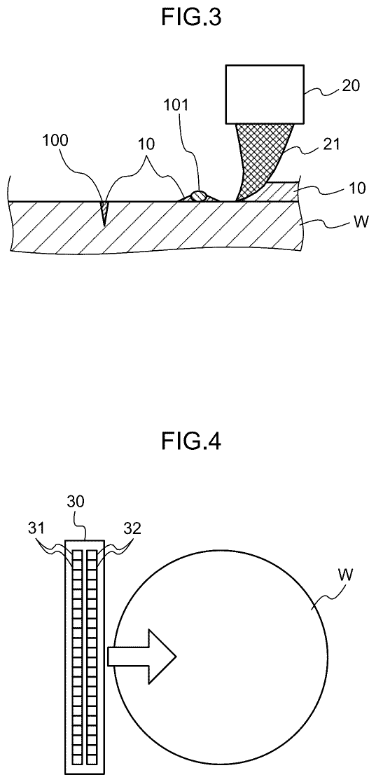

After the film including the fluorescent material is formed on the substrate W at Step S100, the fluorescent material is accumulated in the region having the abnormal shape on the substrate W (S101). Step S101 is one example of a step a). At Step S101, for example, as illustrated in FIG. 3, an excessive film 10 including the fluorescent material is wiped off from the surface of the substrate W by a wiper 20 having an elastic member 21 in a state where the film 10 including the fluorescent material exhibits fluidity. Hereinafter, the operation in which the excessive film 10 including the fluorescent material is wiped off from the surface of the substrate W by the wiper 20 is described as wiping. The surface of the substrate W is subject to the wiping in the state where the film 10 exhibits the fluidity, whereby the film 10 including the fluorescent material accumulates inside the recess 100 and around the protrusion 101 on the substrate W. Thereafter the substrate W is heated or dried, whereby the film 10 including the fluorescent material remaining inside the recess 100 or around the protrusion 101 is accumulated. In the present exemplary embodiment, accumulation refers to a concept that includes aggregation, crystallization, and solidification.

The wiping at Step S101 is a partial removal in which the film 10 including the fluorescent material remains only in the scratches (patterns, grooves, and the like.) on the surface of the target object such as the substrate W and the excessive film 10 including the fluorescent material is removed. Such partial removal method is not limited to the wiping. As the method of the partial removal, other methods such as a method for using physical contact to remove the excessive film 10 including the fluorescent material from the positions other than the target positions and causing crystal distortion in the film 10 including the fluorescent material to derive a mechanochromism reaction may be used. In the present specification, the method in which the physical contact is used to remove the excessive film 10 including the fluorescent material from positions other than the target positions and crystal distortion in the film 10 including the fluorescent material is caused to derive a mechanochromism reaction is defined as a contact method. The wiping is one example of the contact method that removes the film 10 including the fluorescent material adhering to the parts other than the abnormal shapes such as scratches while deriving a mechanochromism reaction.

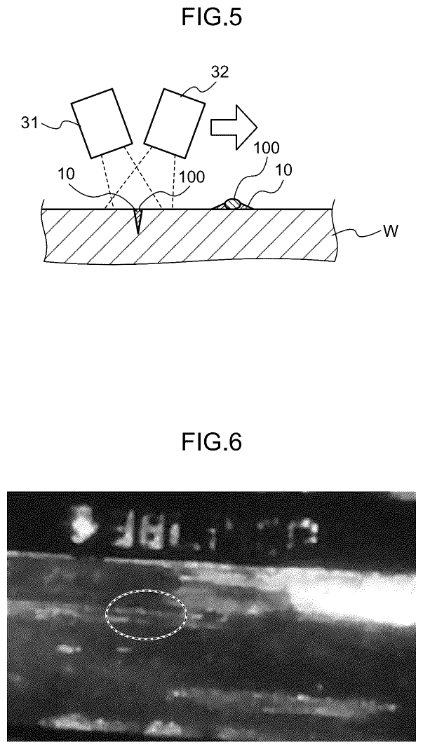

Subsequently, the entire substrate W is scanned using a camera module (S102). Step S102 is one example a step b). At Step S102, for example, as illustrated in FIG. 4, a camera module 30 having a plurality of cameras 31 and a plurality of illuminations 32 scans over the substrate W to acquire an image exhibiting the state of the surface of the substrate W. With each camera 31 and each illumination 32, the surface of the substrate W is irradiated with light from the illumination 32, for example, as illustrated in FIG. 5. The light from the illumination 32 with which the surface of the substrate W is irradiated includes light having wavelengths corresponding to the absorption wavelengths of the fluorescent materials (solid luminescent dye molecules) having the structures illustrated in above Chemical Formulas (1) to (9).

The fluorescent material included in the film 10 accumulated on the recess 100 and the protrusion 101 fluoresces in response to light from the illumination 32. The camera 31 photographs an image of the surface of the substrate W including light emitted from the fluorescent material included in the film 10 accumulated on the recess 100 and the protrusion 101. The image of the surface of the substrate W including light emitted from the fluorescent material included in the film 10 is an example of the fluorescent image of the solid luminescent dye molecules.

The fluorescent materials having the structures illustrated in above Chemical Formulas (1) to (9) fluoresce without the concentration quenching even when the fluorescent materials are accumulated at high concentrations. The fluorescent materials having the structures illustrated in above Chemical Formulas (1) to (9) also increase the luminescence intensity due to the fluorescence when the fluorescent materials are accumulated at high concentrations. Therefore, even in a small region having a size of several tens of nanometers, the region can fluoresce with a large luminescence intensity by densely accumulating the fluorescent materials having the structures illustrated in above Chemical Formulas (1) to (9). This allows the camera module 30 to photograph an image of the region of the film 10 accumulated in a small region having a size of several tens of nanometers.

Subsequently, whether or not the luminescence from the fluorescent material included in the film 10 is detected in the photographed image (S103) is determined. At Step S103, for example, the substrate W is divided into regions having a predetermined size, and with respect to each region, the maximum value of the luminance value of the image when no luminescence from the fluorescent material is detected is previously determined. With respect to the image photographed by the camera module 30, whether or not the maximum value of the luminance value in each region of the substrate W exceeds the predetermined maximum value of the luminance value is determined. In the case where the maximum value of the luminance value in the region of the substrate W exceeds the predetermined maximum value of the luminance value, it is determined that the luminescence from the fluorescent material included in the film 10 is detected in the region.

For example, in the case where the scratch formed on the substrate W is large, the amount of the film 10 of the fluorescent material accumulated on the scratch becomes larger and thus the amount of the fluorescent material accumulated in the scratch becomes also larger. As the amount of the fluorescent material accumulated in the scratch becomes larger, the luminescence intensity of the fluorescent material accumulated in the scratch becomes larger. On the other hand, in the case where the scratch formed on the substrate W is small, the amount of the film 10 of the fluorescent material accumulated in the scratch becomes smaller and thus the amount of the fluorescent material accumulated in the scratch becomes also smaller. As the amount of the fluorescent material accumulated in the scratch becomes smaller, the luminescence intensity of the fluorescent material accumulated in the scratch becomes smaller. Therefore, the size of the scratch (for example, the volume inside the scratch) can be determined by measuring the luminescence intensity of the fluorescent material accumulated in the scratch. The step of determining the size of the scratch based on the intensity of light emitted from the fluorescent material accumulated in the scratch is one example of a step c1).

In the case where the luminescence from the fluorescent material included in the film 10 is not detected in the photographed image (No at S103), it is determined that no abnormal shapes are detected on the substrate W, and the method for observing a surface illustrated in FIG. 1 is terminated.

On the other hand, in the case where the luminescence from the fluorescent material included in the film 10 is detected in the photographed image (Yes at S103), the region on the substrate W where the luminescence is detected is photographed in detail by the camera module 30, and the detailed state of the abnormal shape on the substrate W is photographed (S104). At Step S104, the region where the luminescence is detected may be photographed by enlarging the magnification of the camera module 30 or the state of the surface in the region where the luminescence is detected may be photographed in more detail by using another sensor having high resolution.

The image photographed at Step S104 is notified to the system administrator and the like. The substrate W from which luminescence from the fluorescent material is detected at Step S103 may be removed from the production line as a substrate W in which defects may exist, and the presence or the absence of defects may be analyzed in detail.

Here, the entire substrate W may be photographed from the beginning with a higher magnification of the camera module 30 or photographed using a high-resolution sensor such as an electron microscope. However, this case requires an enormous amount of time to photograph. In addition, in the case where the high-resolution sensor such as an electron microscope is used, the equipment becomes larger. In contrast, in the present exemplary embodiment, the film 10 including the fluorescent material having the structures illustrated in above Chemical Formulas (1) to (9) is accumulated in the region having the abnormal shape on the substrate W in high density, whereby the substrate W having the abnormal shapes having a size of several tens of nanometers can be rapidly identified using the camera module 30. In addition, large equipment such as the high-resolution sensor including an electron microscope is not required, and thus enlarging the equipment can be avoided.

In the case where the process illustrated in FIG. 1 is terminated, with respect to the substrate W that is the target of the inspection, the fluorescent material on the substrate W including the fluorescent material in the scratches can be completely removed without contact by washing with a solvent, irradiating with laser light, thermal sublimation, or the like. This allows the abnormal shapes of the substrate W to be accurately detected without destroying the substrate W.

### Experimental Results

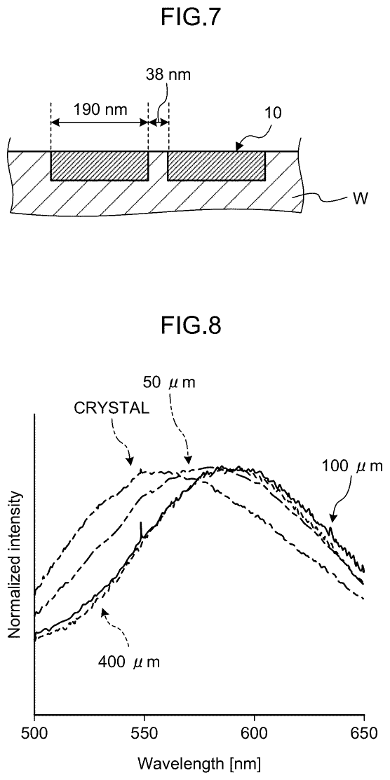

FIG. 6 is a photograph illustrating one example of the image of the surface of the substrate W. In the region surrounded by a dashed line in FIG. 6, the film 10 including the fluorescent material is accumulated in two recesses having a width of 190 nm, as illustrated in the cross-sectional view in FIG. 7. The clearance distance between the two recesses is 38 nm. FIG. 7 illustrates a structure in which the films 10 including the fluorescent materials are integrated on both sides of a protrusion having a size of 38 nm. As illustrated in FIG. 6, the films 10 including the fluorescent material having the structures illustrated in above Chemical Formulas (1) to (9) are accumulated on both sides of the protrusion, whereby the position, size, and shape of the protrusion having a size of 38 nm can be identified from the image. From the results in FIG. 6, it is thought that the position, size, and shape of the recess can be identified from the image even when the width of the recess where the film 10 including the fluorescent material is accumulated is several tens of nanometers.

As described above, the first exemplary embodiment has been explained. As described above, the method for observing a surface in the present exemplary embodiment includes step a) and step b). At step a), a material including at least one or more solid luminescent dye molecules is accumulated in the region having the abnormal shape in the substrate W. At step b), the region having the abnormal shape in the substrate or in the structure on the substrate is irradiated with illumination light to acquire the fluorescent image of the solid luminescent dye molecules. This allows the abnormal shape having a size of several tens of nanometers of the substrate to be accurately detected.

The solid luminescent dye molecules in the exemplary embodiment described above is formed of luminescent dyes that exhibit luminescent mechanochromism. This allows the solid luminescent dye molecules in the present exemplary embodiment to fluoresce without the concentration quenching even when accumulated at a high concentration. In addition, the solid luminescent dye molecules in the present exemplary embodiment can be accumulated at a high concentration, and thus the luminescence intensity by fluorescence can increase. This allows a region to fluoresce with high luminescence intensity even when the region is a small region having a size of several tens of nanometers.

In the exemplary embodiment described above, at step a), the material including the solid luminescent dye molecules on the substrate W is stacked, and thereafter the wiping is performed on the substrate W, whereby the material including the solid luminescent dye molecules is accumulated on the region having the abnormal shape on the substrate W. This allows the material including the solid luminescent dye molecules to be easily accumulated in the region having the abnormal shape on the substrate W.

In the exemplary embodiment described above, the abnormal shape of the substrate W is the scratch formed on the surface of the substrate W. By wiping the material including the solid luminescent dye molecules stacked on the substrate W, the material including the solid luminescent dye molecules is accumulated in the scratch formed on the surface of the substrate W. This allows the material including the solid luminescent dye molecules to be easily accumulated in the region of the scratch formed on the surface of the substrate W. This allows the scratch formed on the surface of the substrate W to be easily observed.

The method for observing a surface in the exemplary embodiment described above may further include step c1). At step c1), the size of the scratch on the surface of the substrate W is determined based on the intensity of light emitted from each region in the fluorescent image. This allows the size of the scratch formed on the surface of the substrate W to be determined.

In the exemplary embodiment described above, the illumination light with which the region of the substrate W is irradiated includes light having a wavelength corresponding to the absorption wavelength of the solid luminescent dye molecules. The solid luminescent dye molecules accumulated in the region having the abnormal shape on the substrate W can emit light.

### Second Exemplary Embodiment

### Experiment

A plurality of scratches having different widths were formed on a glass substrate, and fine powder of crystals of the film 10 including fluorescent materials having the structure illustrated in above Chemical Formulas (1) to (9) was sprayed on the glass substrate. The respective widths of the scratches formed on the surface of the glass substrate are 50 μm, 100 μm, and 400 μm. Thereafter, the fine powder was rubbed onto the glass substrate with a spatula so that the crystal fine powder of the film 10 including the fluorescent material was embedded in the scratches on the glass substrate, and thereafter the excessive fine powder was wiped off.

Observation of scratches on the glass substrate in which particles of the film 10 including the fluorescent material were embedded indicated that the color varied depending on the width of the scratches. In order to examine the differences in the color of the scratches in more detail, measurement of the emission spectrum of the particles of the film 10 including the fluorescent material embedded in the scratches provided the results illustrated in FIG. 8. FIG. 8 is a graph illustrating one example of the distribution of the emission spectra for each scratch width. FIG. 8 also illustrates the distribution of the emission spectrum of the crystal of the film 10 including the fluorescent material.

With reference to FIG. 8, shifts of the emission spectra depending on the widths of the scratches were observed. Specifically, as the scratch width becomes narrower, the emission spectrum distribution shifts toward shorter wavelengths, whereas as the scratch width becomes wider, the emission spectrum distribution shifts toward longer wavelengths.

The fine powder of the crystal of the film 10 including the fluorescent material emitted light in yellow, but when pulverized, it turned to orange. This is thought to be due to the fact that the molecules cannot be moved because the molecules are tightly packed in a crystalline state and thus structural relaxation in an excited state is reduced. This can be explained by the fact that when the molecules become randomly oriented by pulverization, the binding is released, mobility is improved, and a stable structure is formed in the excited state, resulting in acquiring luminescence at a longer wavelength side.

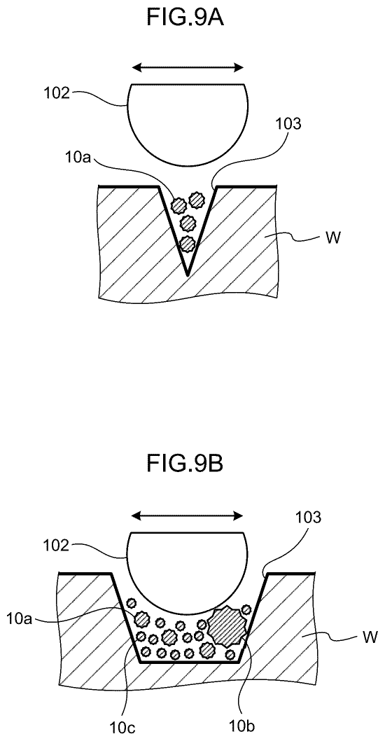

Based on the characteristics of the fluorescent material as described above, the reason why the luminescence color varies depending on the width of the scratch is thought to be that in the case of a narrow scratch, for example, as illustrated in FIG. 9A, particles 10a of the fine powder of the crystal pulverized by a spatula 102 enter a scratch 103. The particles 10a of the fine powder having entered the scratch 103 are not considered to be further pulverized by the spatula 102. Therefore, it is thought that the narrower scratch 103 provides yellow luminescence on the short wavelength side, which is close to the crystalline state.

On the other hand, in the case of the wider scratch, for example, as illustrated in FIG. 9B, it is thought that the particles 10a of the fine powder of the crystal pulverized by the spatula 102 and particles 10b of the fine powder having a larger size than the size of the particles 10a exist in the scratch 103. In addition, it is thought that the frequency of contact with the spatula 102 is increased in the scratch 103 and, in addition to this, a large amount of smaller, more pulverized, particles 10c of the fine powder of the crystal exist. Therefore, it is thought that the luminescence color of the entire fine powder in the scratch 103 changes to the longer wavelength side in the wider scratch 103.

From the experiments described above, the width of the scratch can be estimated by observing the emission spectrum of the fluorescent material embedded in the scratch using the fine powder of the crystal of the film 10 including the fluorescent material having the structures illustrated in above Chemical Formulas (1) to (9). In other words, based on the wavelength of the light emitted from the substrate W in the fluorescent image, the width of the scratch on the surface of the substrate W can be determined. The step of determining the width of the scratch on the surface of the substrate W based on the wavelength of the light emitted from the substrate W in the fluorescent image is one example of step c2).

In the case where there are scratches on the surface of the substrate W, it is assumed that a relatively large amount of the fluorescent material in a particle form maintaining its crystalline state exist in the narrower scratch, whereas the fluorescent material having very small particle diameters to large particle diameters may exist in the wider scratch. Here, the crystals of the molecules that exhibit luminescent mechanochromism vary their luminescence color as the size of a single particle becomes smaller due to mechanical stimulation. Therefore, it is thought that the size of the scratch can be distinguished by the luminescence color because the existence ratio of the particles having different particle diameters (that is, different luminescence colors) varies depending on the width of the scratch. In particular, although images cannot be obtained with optical microscopes in the region having a size of several hundreds of nanometers, the examination of the luminescence color allows the size of the scratch to be measured even in sizes smaller than the applicable region of optical microscopes.

In the experiment, the fine powder of the crystal of the film 10 including the fluorescent material was rubbed onto the glass substrate with the spatula 102 and thereafter the excessive fine powder of the crystal of the film 10 was wiped off. The disclosed technology, however, is not limited thereto. For example, a suspension liquid including the crystal of the film 10 having different particle diameters is prepared, the suspension liquid is applied to the surface of the substrate W, and thereafter the surface of the substrate W is wiped off, for example, by the same method as the method in FIG. 3, whereby the fine powder of the crystal of the film 10 including the fluorescent material may be embedded in the scratch on the substrate W. In addition, the fine powder including the crystal of the film 10 having different particle diameters is sprayed on the substrate W and vibration is applied to the substrate W, whereby the surface of the substrate W may be wiped off, for example, in the same method as the method in FIG. 3 after the fine powder of the crystal of the film 10 including the fluorescent material is embedded in the scratch on the substrate W.

As described above, the second exemplary embodiment has been explained. As described above, the method for observing a surface in the present exemplary embodiment further includes step c2) of determining the width of the scratch in the region of the substrate W based on the wavelength of light emitted from the region of the substrate W in the fluorescent image. This allows the width of the scratch formed on the substrate W to be easily determined.

### Third Exemplary Embodiment

Using a patterned resist, etching, film deposition, or other processes are performed to the substrate W under the resist. At this time, a resist (residue) that cannot be sufficiently removed may remain in the region of the opening of the resist. When such a residue remains in the opening of the resist after patterning, the quality of subsequent etching and film deposition at the position of the opening degrades.

Therefore, in the present exemplary embodiment, the resist is patterned with a resist in which the solid luminescent dye molecules are mixed. Thereafter, the intensity of light emitted from the solid luminescent dye molecules in the resist is measured for each predetermined region. In the case where the measured light intensity exceeds the intensity of light from the solid luminescent dye molecules estimated from the pattern of the resist to be formed in the region, it can be determined that more resist remains than the amount of the resist to be formed in the region. Therefore, whether or not the resist residue remains in the region can be determined by measuring the intensity of light emitted from the solid luminescent dye molecules included in the resist in each predetermined region. The patterned resist is one example of the structure on the substrate W. The resist residue is one example of an abnormal shape in the structure on the substrate W.

### Method for Observing Surface

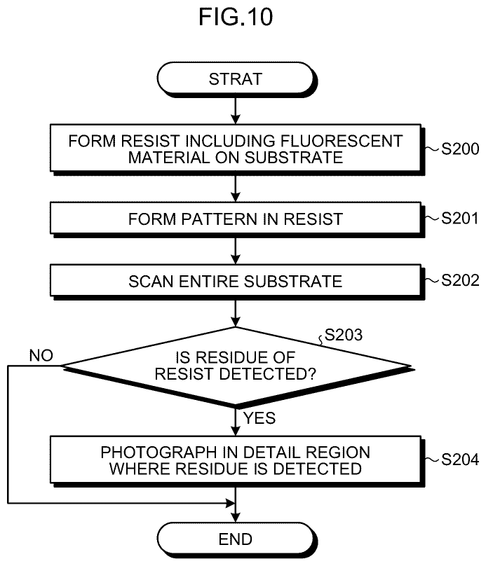

FIG. 10 is a flowchart illustrating one example of the method for observing a surface in the third exemplary embodiment. Each process in the flowchart exemplified in FIG. 10 is achieved by controlling each device using, for example, the computer 90 exemplified in FIG. 16.

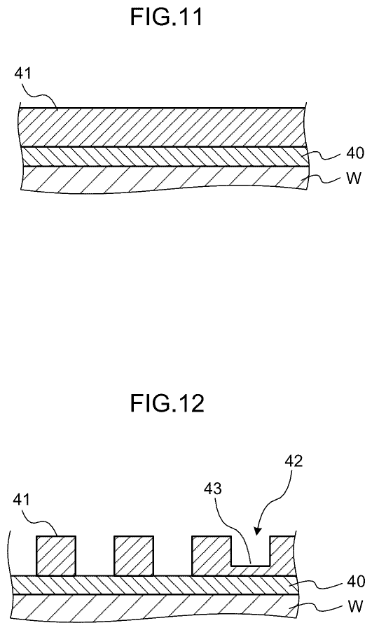

First, a resist including the fluorescent material (solid luminescent dye molecules) is formed on a substrate (S200). At Step S200, as illustrated in FIG. 11, for example, an antireflection film 40 is formed on the substrate W and a resist 41 including the fluorescent material is formed on the antireflection film 40. The resist 41 is formed on the antireflection film 40 by, for example, spin coating.

In the present exemplary embodiment, for example, methoxypropyl acetate illustrated in Chemical Formula (10) below is used as a resist material. The resist material, however, is not limited to methoxypropyl acetate.

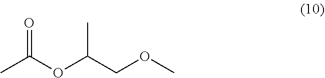

In the present exemplary embodiment, for example, at least one of the solid luminescent dye molecules having the structures illustrated in following Chemical Formulas (11) to (14) is used as the fluorescent material included in the resist.

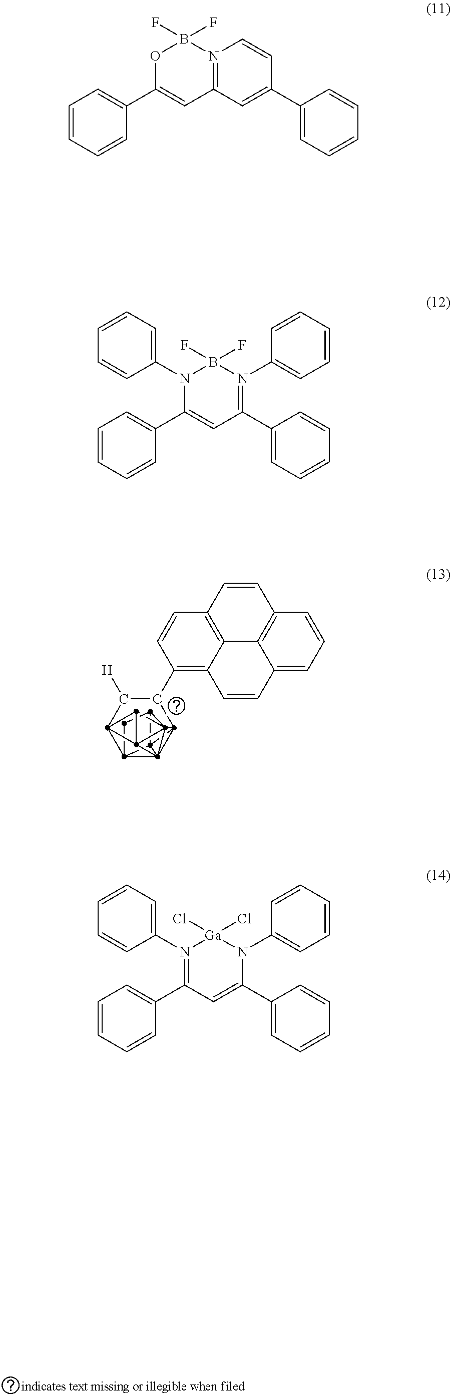

In above Chemical Formula (13), the black circle represents a BH group having boron and hydrogen.

Subsequently, light exposure and development are performed to the resist 41 to form a predetermined pattern on the resist 41 (S201). Step S201 is one example of step a1). At Step S201, for example, the resist 41 is exposed by being irradiated with UV light from a KrF (krypton-fluoride) light source or the like to the region of the resist 41 to be removed along a predetermined pattern. The exposed resist 41 is dissolved with a chemical solution and removed. This allows a pattern, for example, as illustrated in FIG. 12 to be formed on the resist 41.

Here, in an opening 42 formed in the resist 41, a residue 43 may remain in the opening 42, for example, as illustrated in FIG. 12 due to an insufficient light exposure amount. When the residue 43 remains in the opening 42, the quality of subsequent etching and film deposition at the position of the opening 42 may degrade. In the case where the residue 43 is detected in the opening 42, a process to remove the residue 43 is required.

Subsequently, the entire substrate W is scanned using the camera module 30 (S202). At Step S202, the surface of the substrate W is scanned using, for example, the camera module 30 illustrated in FIG. 4 and an image (fluorescent image) indicating a state of the surface of the substrate W is acquired.

Subsequently, whether or not the residue 43 of the resist 41 is detected is determined (S203). At Step S203, the surface of the substrate W is divided into a predetermined number of regions, and with respect to each region, the intensity (reference intensity) of light from the fluorescent material (solid luminescent dye molecules) estimated from the resist pattern that should be formed in that region is predetermined by experiment or other means. Based on the image (fluorescent image) in which the surface of the substrate W is photographed, with respect to each region, whether or not the light intensity detected from the image exceeds the reference intensity is determined. With respect to each region, in the case where the light intensity detected from the image exceeds the reference intensity, it is determined that a more mount of the resist 41 remains than the amount of the resist 41 that should remain in the region and the residue 43 remains.

Here, in the present exemplary embodiment, the light intensity depending on the amount of the resist 41 is measured because the resist 41 includes the solid luminescent dye molecules having the structures illustrated in above Chemical Formulas (11) to (14). Although the resist 41 itself also fluoresces, the intensity of the light emitted from the resist 41 is lower than the intensity of the light emitted from the solid luminescent dye molecules having the structures illustrated in above Chemical Formulas (11) to (14).

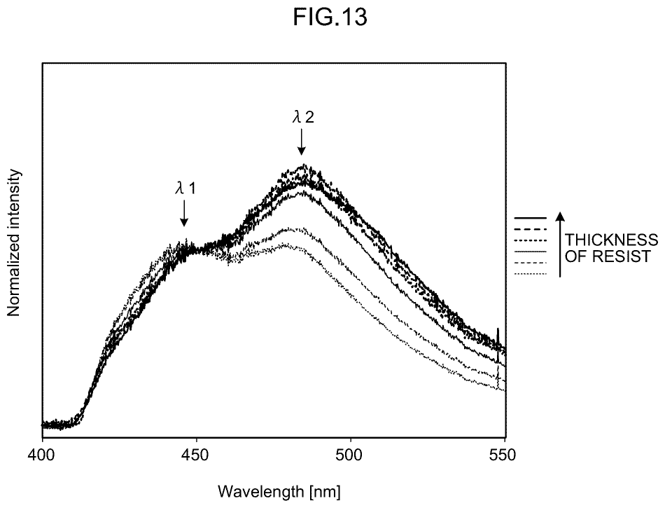

FIG. 13 is a graph illustrating one example of the distribution of luminescence intensity for each thickness of the resist 41. FIG. 13 is normalized by the luminescence intensity at a wavelength λ1 of the light emitted by the resist 41 itself. λ2 in FIG. 13 indicates the wavelength of the light emitted from the solid luminescent dye molecules. For example, as illustrated in FIG. 13, the luminescence intensity at the wavelength λ2 emitted from the solid luminescent dye molecules increases as the thickness of the resist 41 increases. Therefore, measuring the luminescence intensity at the wavelength λ2 emitted from the solid luminescent dye molecules allows the luminescence intensity to be detected depending on the amount of the resist 41 existing in the target region on the substrate W. This allows the amount of the resist 41 that should be formed in the region on the substrate W and the amount of the resist 41 that actually exists in that region to be compared.

Here, the resist 41 itself also emits light at the wavelength λ1, but its luminescence intensity is small. In contrast, the solid luminescent dye molecules having the structures illustrated in above Chemical Formulas (11) to (14) do not undergo the concentration quenching even when the concentration in the resist 41 increases. Therefore, the solid luminescent dye molecules having the structures illustrated in above Chemical Formulas (11) to (14) can be mixed in the resist 41 at high concentrations to provide large luminescence intensity. Therefore, as illustrated in FIG. 13, for example, not the luminescence intensity at the wavelength λ1 of the resist 41 itself but the luminescence intensity at the wavelength λ2 of the solid luminescent dye molecules included in the resist 41 can increase the change in the luminescence intensity corresponding to the change in the film thickness of the resist 41. Therefore, the amount of the resist 41 can be more accurately estimated by the estimation of the amount of the resist 41 based on the luminescence intensity at the wavelength λ2 of the solid luminescent dye molecules in the resist 41 than by the estimation of the amount of the resist 41 based on the luminescence intensity at the wavelength λ1 of the resist 41 itself.

In the case where the residue 43 is detected in the opening 42 of the resist 41 at Step S203, the detailed position of the residue 43 is identified at Step S204, and light exposure and development may be performed again at the position on the substrate W where the residue 43 is detected.

In this case, the thickness of the residue 43 may be estimated from the difference between the luminescence intensity serving as the reference and the detected luminescence intensity in the region on the substrate W where the residue 43 is detected. In other words, the thickness of the resist 41 remaining in the opening 42 may be determined based on the intensity of light emitted from each region in the fluorescent image. The step of determining the thickness of the resist 41 remaining in the opening 42 based on the intensity of light emitted from each region in the fluorescent image is one example of step c3).

The light exposure may be performed again by irradiating the substrate W at the position where the residue 43 is detected with the light having the light exposure amount necessary to remove the residue 43 having the estimated thickness. In other words, the residue 43 remaining in the opening 42 may be removed by irradiating the opening 42 in which the residue 43 remains with the light having the light exposure amount necessary to remove the resist 41 having the determined thickness. The step of removing the residue 43 remaining in the opening 42 by irradiating the opening 42 in which the residue 43 remains with the light having the light exposure amount necessary to remove the resist 41 having the determined thickness is one example of step d).

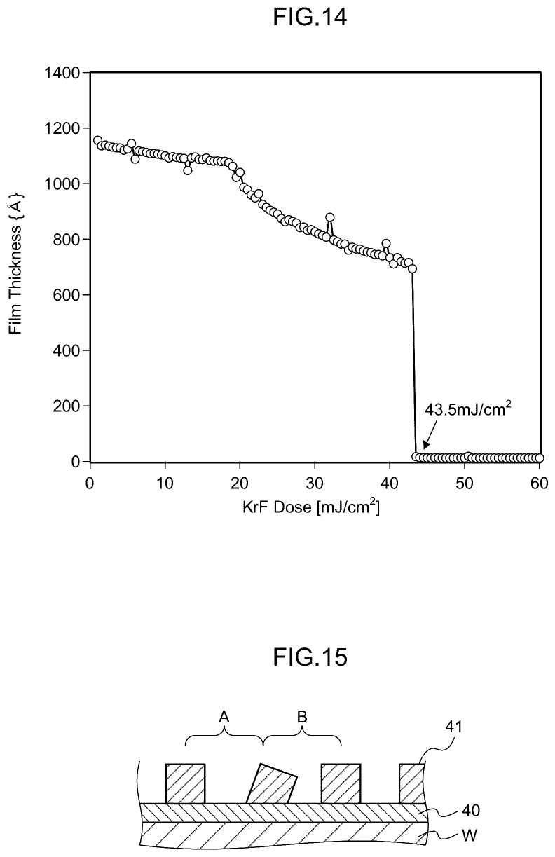

FIG. 14 is a graph illustrating one example of the relationship between the thickness of the resist 41 and the light exposure amount. In FIG. 14, the film thickness of the resist 41 remaining after development at each light exposure amount is plotted when the light exposure amount is changed for the resist 41 having a predetermined film thickness. For example, from the experimental results as illustrated in FIG. 14, the light exposure amount required to remove the residue 43 can be calculated for the film thickness of the residue 43.

In the third exemplary embodiment described above, the presence or the absence of the residue 43 is determined from the comparison between the luminescence intensity serving as the reference and the detected luminescence intensity in the regions on the substrate W. The disclosed technology, however, is not limited thereto. For example, as illustrated in FIG. 15, the technology of the present exemplary embodiment can be applied to detect pattern collapse of the resist 41 after pattern formation.

For example, in a region A in FIG. 15, the amount of the resist 41 is smaller than the designed value because a part of the resist 41 in the region A falls outside of the region A. Therefore, in the region A, the detected luminescence intensity is a smaller value than the value of the luminescence intensity serving as the reference. On the other hand, in a region B adjacent to the region A, the amount of the resist 41 is larger than the designed value because a part of the resist 41 in the region B falls inside the region B. Therefore, in the region B, the detected luminescence intensity is a larger value than the value of the luminescence intensity serving as the reference. As described above, the pattern collapse of the resist 41 can be detected by comparing the luminescence intensity serving as the reference and the detected luminescence intensity with respect to the adjacent regions.

### Hardware

The control in each of the above exemplary embodiments is achieved by, for example, the computer 90 as illustrated in FIG. 16. FIG. 16 is a view illustrating one example of the hardware configuration of the computer 90. The computer 90 has a CPU (Central Processing Unit) 91, a RAM (Random Access Memory) 92, a ROM (Read Only Memory) 93, and an auxiliary storage device 94. The computer 90 is also equipped with a communication interface (I/F) 95, an input/output interface (I/F) 96, and a media interface (I/F) 97.

The CPU 91 operates based on a computer program stored in the ROM 93 or the auxiliary storage device 94 to control each part. The ROM 93 stores therein a boot program to be executed by the CPU 91 when the computer 90 is started up and computer programs that depend on the hardware of the computer 90.

The auxiliary storage device 94 is, for example, an HDD (Hard Disk Drive) or an SSD (Solid State Drive), which stores therein computer programs executed by the CPU 91, data used by the computer programs, and the like. The CPU 91 reads the computer program from the auxiliary storage device 94, loads the computer program onto the RAM 92, and executes the loaded computer program. The communication I/F 95 receives signals and data from the camera module 30, a film forming apparatus, a developer equipment, and the like through a communication NW (NetWork) such as LAN (Local Area Network) and sends them to the CPU 91. The communication I/F 95 transmits signals and data generated by the CPU 91 to the camera module 30, the film forming apparatus, the developer equipment, and the like through the communication NW.

The CPU 91 controls an input device and an output device through the input/output I/F 96. The CPU 91 acquires signals input from the input device through the input/output I/F 96 and sends them to the CPU 91. The CPU 91 also outputs the generated data to the output device through the input/output I/F 96.

The media I/F 97 reads computer programs or data stored on a recording media 98 and stores them in the auxiliary storage device 94. The recording medium 98 is, for example, optical recording media such as a DVD (Digital Versatile Disc) and a PD (Phase change rewritable Disc), magneto-optical recording media such as an MO (Magneto-Optical Disk), tape media, magnetic recording media, semiconductor memories, or the like.

The CPU 91 of the computer 90 executes the computer program loaded on the RAM 92 to achieve each of the processes exemplified in the flowchart in FIG. 1 or FIG. 10. The CPU 91 of the computer 90 reads the computer program loaded on the RAM 92 from the recording medium 98 and stores the computer program in the auxiliary storage device 94. As another example, the CPU 91 of the computer 90 may acquire the computer program from another device through the communication NW and store the computer program in the auxiliary storage device 94.

The exemplary embodiments disclosed herein should be considered as exemplification in all respects and as not restrictive. Indeed, the above exemplary embodiments can be realized in a variety of forms. The above exemplary embodiments may also be omitted, replaced, or modified in various forms without departing from the scope and gist of the appended claims.

With respect to the above exemplary embodiments, the following notes are further disclosed.

According to various aspects and exemplary embodiments of the present disclosure, the abnormal shape in the substrate or in the structure on the substrate having a size of several tens of nanometers can be accurately detected.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for observing a surface, the method comprising:
a) accumulating a material including at least one or more solid luminescent dye molecules in a region having an abnormal shape in a substrate or in a structure on the substrate; and
b) acquiring a fluorescent image of the solid luminescent dye molecules by irradiating the region with illumination light.

2. The method for observing a surface according to claim 1, wherein the solid luminescent dye molecules include molecules of a luminescent dye exhibiting luminescent mechanochromism.

3. The method for observing a surface according to claim 1, wherein at the a), the material is accumulated in the region having the abnormal shape on the substrate by performing wiping on the substrate after the material is stacked on the substrate.

4. The method for observing a surface according to claim 3, wherein
the abnormal shape on the substrate is a scratch formed on a surface of the substrate, and
the material stacked on the substrate is accumulated in the scratch by a contact method.

5. The method for observing a surface according to claim 4, wherein the contact method is for accumulating the material stacked on the substrate in the scratch by wiping off the surface of the substrate with an elastic member.

6. The method for observing a surface according to claim 4, further including c1) determining a size of the scratch in each region based on light intensity emitted from each region in the fluorescent image.

7. The method for observing a surface according to claim 4, further including c2) determining a width of the scratch in each region based on a wavelength of light emitted from each region in the fluorescent image.

8. The method for observing a surface according to claim 1, further including
a1) forming a resist including the solid luminescent dye molecules on the substrate and forming an opening having a predetermined pattern in the resist before the a), wherein
the material is the resist, and
the abnormal shape in the structure on the substrate at the a) is the resist remaining in the opening.

9. The method for observing a surface according to claim 8, further including c3) determining a thickness of the resist remaining in the opening based on intensity of light emitted from each region in the fluorescent image.

10. The method for observing a surface according to claim 9, further including d) removing the resist remaining in the opening by irradiating the opening in which the resist remains with light having a required light exposure amount for removing the resist having a determined thickness.

11. The method for observing a surface according to claim 1, wherein the illumination light with which the region is irradiated at the b) includes light having a wavelength corresponding to an absorption wavelength of the solid luminescent dye molecules.
